(19) United States
(12) Patent Application Publication
(10) Pub. No.: US 2024/0431116 A1
(43) Pub. Date: Dec. 26, 2024

(54) FEFET DEVICE

(71) Applicant: Taiwan Semiconductor Manufacturing Company, Ltd., Hsinchu (TW)

(72) Inventors: Kuo-Chang Chiang, Hsinchu City (TW); Chung-Te Lin, Tainan City (TW); Yu-Ming Lin, Hsinchu City (TW); Po-Ting Lin, Taichung City (TW); Yu-Chuan Shih, Hsinchu City (TW)

(21) Appl. No.: 18/338,414

(22) Filed: Jun. 21, 2023

(51) Int. Cl. H10B 51/30; H01L 29/51; H01L 29/66; H01L 29/78; H01L 29/786

(52) U.S. Cl. CPC H10B 51/30; H01L 29/516; H01L 29/66969; H01L 29/78391; H01L 29/7869

(57) ABSTRACT

The present disclosure relates a ferroelectric field-effect transistor (FeFET) device. The FeFET device includes a ferroelectric structure having a first side and a second side. A gate structure is disposed along the first side of the ferroelectric structure, and an oxide semiconductor is disposed along the second side of the ferroelectric structure. The oxide semiconductor has a first semiconductor type. A source region and a drain region are disposed on the oxide semiconductor. The gate structure is laterally between the source region and the drain region. A polarization enhancement structure is arranged on the oxide semiconductor between the source region and the drain region. The polarization enhancement structure includes a semiconductor material or an oxide semiconductor material having a second semiconductor type that is different than the first semiconductor type.

### BACKGROUND

Many modern day electronic devices include non-volatile memory. Non-volatile memory is electronic memory that is able to store data when powered and also in the absence of power. A promising candidate for the next generation of non-volatile memory is ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a ferroelectric field-effect transistor (FeFET) device having a ferroelectric/anti-ferroelectric hybrid layer.

FIG. 2 shows a close-up view of some embodiments of a multi-grain crystal structure of a ferroelectric layer or anti-ferroelectric layer.

FIG. 3 illustrates a cross-sectional view of an integrated circuit where a FeFET device is disposed in between adjacent metal layers of an interconnect structure of the integrated circuit.

FIG. 4 illustrates a cross-sectional view of an integrated circuit where a FeFET device has a gate structure whose height corresponds to a gate electrode of a metal oxide semiconductor field effect transistor (MOSFET) on the integrated circuit.

FIG. 5 illustrates a cross-sectional view of an integrated circuit where a FeFET device has a gate structure that corresponds to a doped region in a substrate of the integrated circuit.

FIG. 6 illustrates a perspective view of an integrated circuit including a FeFET device as part of a three-dimensional memory array.

FIG. 7 illustrates an exemplary schematic diagram of FeFET memory circuit having a memory array comprising FeFET devices respectively having a ferroelectric/anti-ferroelectric hybrid layer.

FIG. 8 illustrates a plot of gate voltage versus drain current for FeFET devices in accordance with some embodiments.

FIGS. 9-15 illustrate cross-sectional views of some embodiments of a method of forming an integrated chip comprising a ferroelectric/anti-ferroelectric hybrid layer.

FIG. 16 illustrates a flow diagram of some embodiments of a method of forming an integrated chip comprising a FeFET device having a ferroelectric/anti-ferroelectric hybrid layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric field-effect transistor (FeFET) device is a type of ferroelectric device comprising ferroelectric material arranged between a conductive gate structure and a channel region, where the channel region is disposed between a source region and a drain region. During operation of the FeFET device, applying a gate voltage to the gate structure generates an electric field that establishes a dipole moment within the ferroelectric material. Depending on a value of the gate voltage, a direction of the dipole moment (e.g., a polarization) may be in one various discrete directions. Since a threshold voltage (e.g., a minimum gate-to-source voltage that forms a conductive path between the source region and the drain region) of a FeFET device is dependent upon the polarization within the ferroelectric material, the different polarizations effectively split the threshold voltage of the FeFET device into distinct values corresponding to different data states. The polarization states are maintained when the gate voltage/electric field is removed.

A ferroelectric device that includes a ferroelectric dominant lattice structure has only one positive polarization state and only one negative state, for a total of two states which may be used to store one bit in a single memory cell. In contrast, a ferroelectric device that includes an anti-ferroelectric dominant lattice structure has two positive polarization states and two negative polarization states, for a total of four states which may be used to store two digital bits in a single memory cell. Thus, adopting anti-ferroelectric dominant material can allow for twice the amount of data to be stored in the same footprint, thereby reducing memory sizes and/or increasing data storage densities compared to memory cells made of solely ferroelectric dominant material.

One way to fabricate ferroelectric devices with an anti-ferroelectric dominant lattice structure is to increase a percentage of dopants in a ferroelectric material. For example, for a hafnium (Hf) zirconium (Zr) oxide (O) (HZO) (e.g., Hf₁₋ₓZrₓO) ferroelectric device, increasing a Zr molar/dopant concentration (e.g., x) to be greater than 70% can achieve a tetragonal lattice structure with anti-ferroelectric properties. This makes the HZO recipe more complicated and may lead to uneven Hf/Zr distribution in the HZO film. In addition, Zr-rich HZO shows a strong wake-up effect where the polarization increases over time as the number of write/read electric field cycles is increased. The wake-up effect negatively affects endurance and causes performance instability. Further, ferroelectric devices with high Zr dopant concentrations can suffer from undesirable current leakage, which ultimately degrades the performance and/or stability of the FeFET devices. This current leakage can arise, for example, from device fatigue as the devices ages, and/or can arise as defects are generated over time during polarization switching. For instance, if there are a large number of oxygen defects in the oxide semiconductor and/or ferroelectric film, this can lead to a potential pathway for device breakdown.

Accordingly, in view of the above, various embodiments of the present disclosure relate to an integrated chip having a FeFET device comprising a ferroelectric structure that includes a ferroelectric layer and an anti-ferroelectric layer with improved endurance properties. In particular, the ferroelectric layer exhibits a dominant orthorhombic crystalline structure that exhibits ferroelectric properties, while the anti-ferroelectric layer exhibits a dominant tetragonal crystalline structure that exhibits anti-ferroelectric properties. An interlayer separates the ferroelectric layer from the anti-ferroelectric layer, and enhances tetragonal crystalline grain growth in the anti-ferroelectric layer. The interlayer also acts to suppress current leakage, for example by promoting the formation of large grains in the ferroelectric structure to help suppress current leakage through defects.

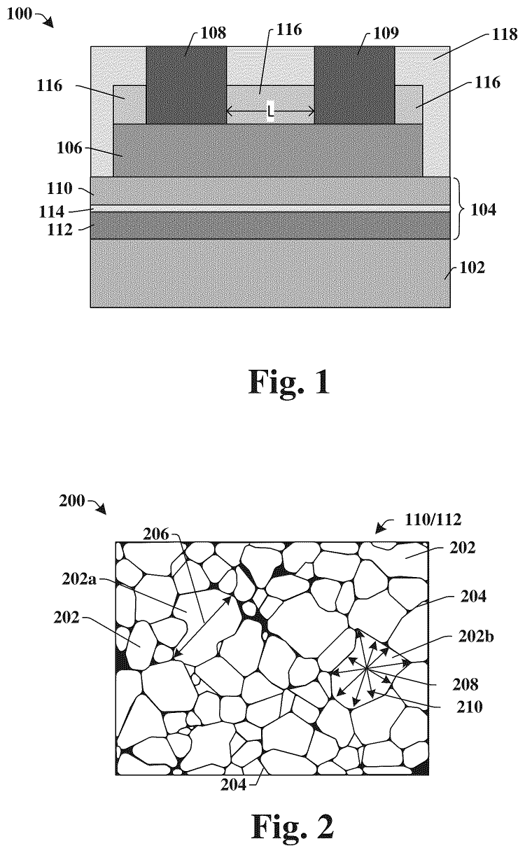

FIG. 1 illustrates a cross-sectional view of a ferroelectric field-effect transistor (FeFET) device 100 in accordance with some embodiments. The FeFET device 100 comprises a ferroelectric structure 104, which is arranged between an oxide semiconductor 106 and a conductive gate structure 102. A source region 108 and a drain region 109 are also arranged over the oxide semiconductor 106 and are separated from the ferroelectric structure 104 by the oxide semiconductor 106. In the illustrated embodiment of FIG. 1, the gate structure 102 extends an entire channel length, L, (e.g., ranging from 3 nanometers (nm) to 100 nm) between the source region 108 and drain region 109, but in other embodiments, the gate structure 102 may laterally extend only partially between the source region 108 and the drain region 109. A capping structure 116, which for example can comprise silicon dioxide and/or a high-k dielectric material (e.g., HfO₂, Al₂O₃, TiO₂), can reside over the oxide semiconductor 106 and can have sidewalls aligned with outer sidewalls of the oxide semiconductor 106. The capping structure 116 can have a thickness of 10 angstroms to 200 angstroms. A dielectric structure 118, such as a silicon dioxide layer, or low-k dielectric layer, can surround the capping structure 116 and oxide semiconductor 106.

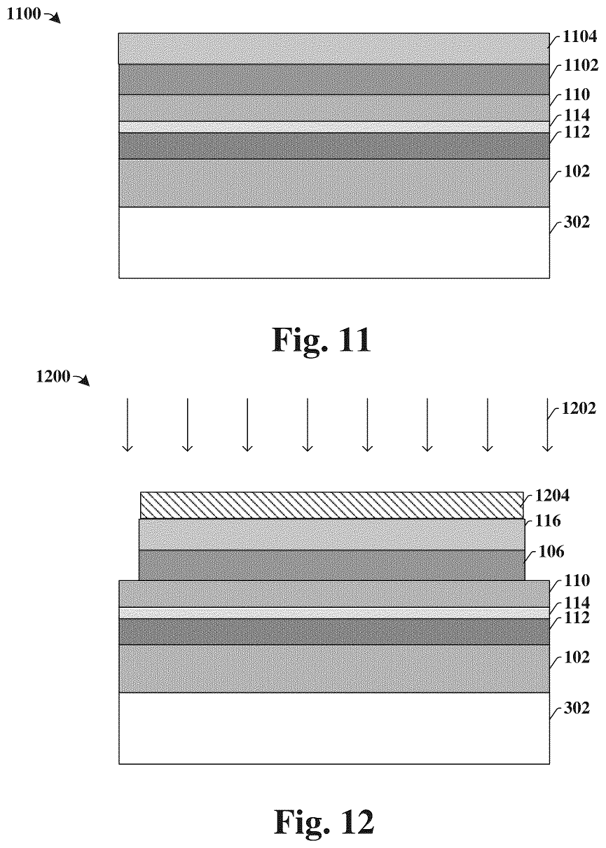

In some embodiments, the oxide semiconductor 106 comprises one or more of indium gallium oxide (IGO), indium gallium zinc oxide (IGZO), indium gallium zinc tin oxide, indium tungsten oxide (IWO), indium tungsten zinc oxide, indium zinc oxide (IZ), zinc oxide, and/or Sn-doped oxide semiconductor materials. In some cases, the oxide semiconductor 106 comprises InₓGa_{y}Zn_{z}MO, where M can be Ti, Al, Ag, W, Ce, or Sn; and x, y, and Z each range between 0 and 1. The gate structure 102, source region 108, and drain region 109 can each have a thickness of between 50 angstroms and 500 angstroms, and can comprise a metal, such as tantalum nitride (TaN), titanium (Ti), Tungsten (W), Titanium nitride (TiN), molybdenum, copper, gold, zinc, aluminum, or the like. In various embodiments, the gate structure 102 corresponds to a wordline of a FeRAM device (see e.g., FIG. 7, discussed further herein).

Compared to related FeFET devices which include only a single ferroelectric layer, the ferroelectric structure 104 of FIG. 1 includes a ferroelectric layer 110 that exhibits ferroelectric properties and an anti-ferroelectric layer 112 that exhibits anti-ferroelectric properties. An interlayer 114 separates the ferroelectric layer 110 from the anti-ferroelectric layer 112, and acts to impede crystal growth between the ferroelectric layer 110 and the anti-ferroelectric layer 112, while concurrently inducing larger crystalline growth on either side of the interlayer 114, which can help to reduce current leakage.

The ferroelectric layer 110 can comprise hafnium oxide, such as Hf₁₋ₓZrₓO, or similar, and the anti-ferroelectric layer 112 can also comprise hafnium oxide, such as Hf_{1-y}Zr_{y}O, where x and y are molar concentrations of Zr and are different from one another. In some cases, x is less than 0.70, which can provide homogenous Zr distribution through the HZO lattice and reduce wake-up effect. For example, x can range between 0 and 0.5, and y can range between 0.5 and 1. The ferroelectric layer 110 can be thicker than the anti-ferroelectric layer 112, can have the same thickness as the anti-ferroelectric layer 112, or can be thinner than the anti-ferroelectric layer 112.

The ferroelectric layer 110 can have a lattice with a different orientation than that of the anti-ferroelectric layer 112. For example, the ferroelectric layer 110 can have a predominantly orthorhombic crystal lattice while the anti-ferroelectric layer 112 has a predominantly tetragonal crystal lattice. Thus, the ferroelectric layer has a first percentage of tetragonal crystalline lattice per unit volume and the anti-ferroelectric layer has a second percentage of tetragonal crystalline lattice per unit volume, wherein the second percentage is greater than the first percentage. Further, the ferroelectric layer 110 can be more than 50% of orthorhombic crystalline lattice per unit volume, more than 70% of orthorhombic crystalline lattice per unit volume, or even more than 90% of orthorhombic crystalline lattice per unit volume; and the anti-ferroelectric layer 112 can have more than 50% of tetragonal crystalline lattice per unit volume, more than 70% of tetragonal crystalline lattice per unit volume, or even more than 90% of tetragonal crystalline lattice per unit volume. In some cases, a percentage of orthorhombic crystalline lattice per unit volume in the ferroelectric layer 110 is greater than a percentage of tetragonal crystalline lattice per unit volume in the anti-ferroelectric layer 112. For instance, in some examples, a ratio of the percentage of orthorhombic crystal per unit volume in the ferroelectric layer 110 to the percentage of tetragonal crystal per unit volume in the anti-ferroelectric layer 112 is in a range of 15:1 to 25:1. Such ratios of crystalline lattice structures can help provide the ferroelectric and anti-ferroelectric properties.

In some cases, the interlayer 114 comprises a metal oxide, such as titanium oxide, aluminum oxide, magnesium oxide, hafnium oxide, or indium oxide; or a metal, such as titanium, platinum, gold, or nickel. In some cases, the interlayer has a coefficient of thermal expansion of 1×10-6 meters (m)/Kelvin (K) to 1×10-4/K. The interlayer 114 can have a thickness of less than 1 nm, which promotes high quality crystal growth on surfaces of the interlayer 114.

The interlayer 114 provides a break between crystalline lattices of the ferroelectric layer 110 and anti-ferroelectric layer 112, and promotes a dominant phase of the ferroelectric structure 104 from the orthorhombic phase to the tetragonal phase. By properly introducing the interlayer 114, the anti-ferroelectric properties are induced in the ferroelectric structure 104 without the need to increase Zr doping level. Thus, compared to other approaches with high Zr doping (where x in Hf(1−x)ZrxO is greater than 0.7), Zr doping of less than 70% can be used for the ferroelectric structure 104 so dopants are more evenly distributed, and wake-up effect is reduced. Thereby, stability of the ferroelectric structure can be improved with better ferroelectric endurance.

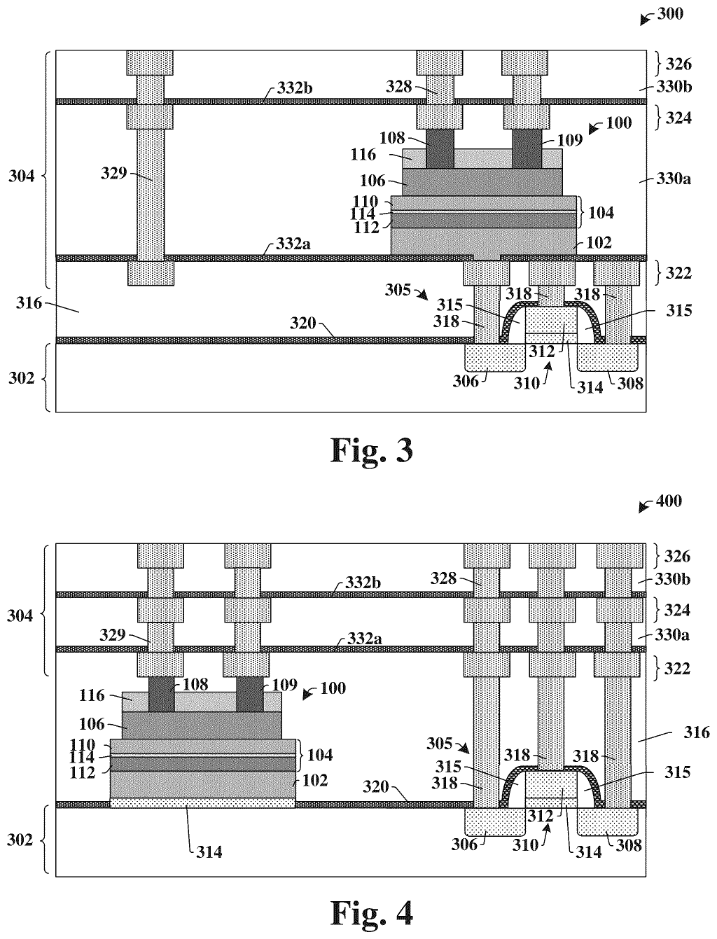

Further still, in some examples, due to the presence of the interlayer 114, the ferroelectric layer 110 and/or anti-ferroelectric layer 112 can have a maximum grain size width and/or average grain size of more than 20 microns, which can be significantly larger than conventional grain sizes and can help to reduce current leakage along grain boundaries within ferroelectric structure 104. Referring briefly to FIG. 2, which shows a close-up view of a crystalline structure 200 corresponding to ferroelectric layer 110 or anti-ferroelectric layer 112, the crystalline structure 200 is made of crystalline grains 202 that are separated by grain boundaries 204. As shown by line 206, a maximum grain size width can be measured from one edge of a grain 202a to another edge of the grain 202a using a straight line (206) through the grain that results in the largest width measurement of the grain 202a. Again, in some cases this maximum grain size width represented by line 206 can be more than 20 microns. In other cases, the crystalline structure 200 can have an average grain size of more than 20 microns. This average grain size can be measured by picking a central point 208 on a grain 202b, then measuring a distance along an outwardly extending line 210 (e.g., radius) until the edge of the grain 202b is reached, and measuring additional distances from the central point 208 using additional outwardly extending lines in this fashion until a representative number of lines is reached, and then averaging the distances of those lines and multiplying by two to find an approximate grain size (e.g., diameter) of the grain 202b. This process can be repeated for other grains, and an average grain size can be determined for the entire the ferroelectric layer 110 and/or entire anti-ferroelectric layer 112.

Although FIG. 1 has illustrated the ferroelectric structure 104 in the context of a FeFET device 100, it will be appreciated that the ferroelectric structure 104 can also be included in other devices, for example, such as a metal-ferroelectric-metal (MFM) capacitor structure. Further, in some cases, the orientation of the ferroelectric layer 110 and anti-ferroelectric layer 112 can be “flipped”, such that the ferroelectric layer 110 is closer to the gate structure 102 and the anti-ferroelectric layer 112 is closer to the oxide semiconductor 106.

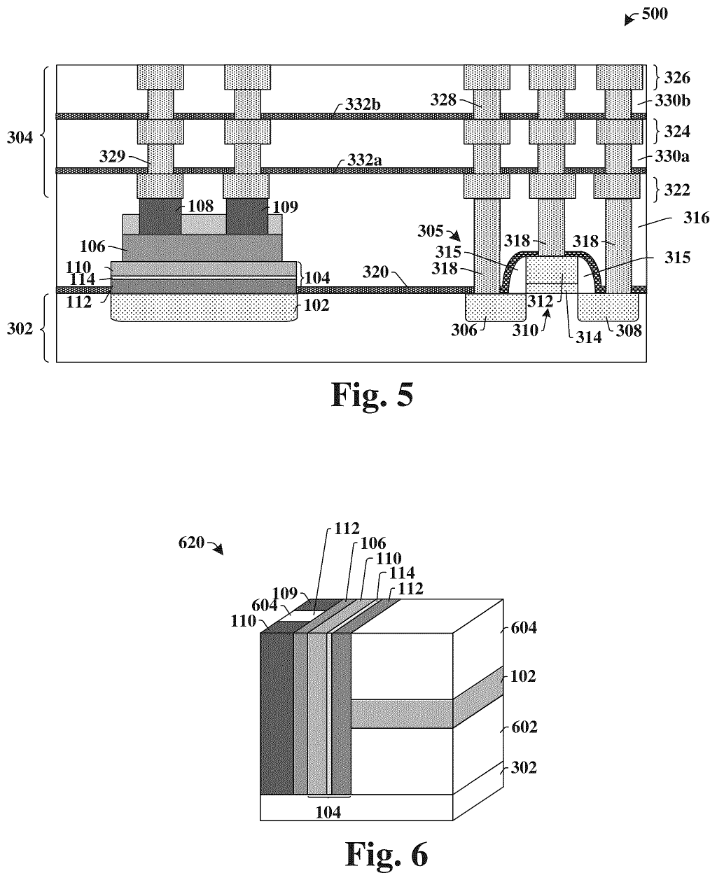

FIGS. 3-6 illustrate several examples of how the FeFET device 100 can be included as part of an integrated circuit with other devices and interconnect (e.g., wiring) structures.

FIG. 3 shows some embodiments of an integrated circuit 300 that includes a semiconductor substrate 302 with an interconnect structure 304 over the semiconductor substrate 302, and wherein the FeFET device 100 is arranged between adjacent metal lines in the interconnect structure 304. The semiconductor substrate 302 can manifest as a monocrystalline silicon substrate, a semiconductor on insulator (SOI) substrate, or some other semiconductor substrate.

A semiconductor device including multiple device terminals is disposed in and/or over the substrate. In the illustrated example, the semiconductor device is a MOSFET 305, but in other examples the semiconductor device could be another active device (e.g., bipolar junction transistor (BJT), FinFET, or junction FET (JFET) among others), a passive device (e.g., diode, resistor, or capacitor, among others). The illustrated MOSFET 305 includes a source region 306 and a drain region 308, both of which have a first conductivity type. A channel region 310 separates the source region 306 and drain region 308 and has a second conductivity type opposite the first conductivity type. A conductive gate electrode 312 is disposed over the channel region 310 and can comprise doped polysilicon or metal. A gate dielectric 314, which can be made of silicon dioxide or a high-k dielectric material, separates the gate electrode 312 from the channel region 310. Sidewall spacers 315, which can be made for example of silicon nitride, are disposed on outer edges of the gate electrode 312. A dielectric layer 316, such as silicon dioxide or a low-k dielectric is disposed over the gate electrode 312 and source region 306 and drain region 308. Contacts 318, which are made of a metal (e.g., tungsten, copper, aluminum, titanium, nickel, and/or tantalum), extend vertically from the source region 306, drain region 308 and gate electrode 312 though the dielectric layer 316 and through an etch stop layer 320.

The interconnect structure 304 include a first metal layer 322, second metal layer 324, and third metal layer 326, as well as higher metal layers (not shown). Each of these metal layers can include metal lines that extend into the plane of the page and/or across the page to connect semiconductor device (e.g., MOSFET 305) to one another, thereby achieving a desired circuit configuration. Vias (e.g., 328, 329) extend vertically through one or more of a plurality of stacked interlayer dielectric (ILD) layers 330a-330b and between adjacent metal layers to couple metal layers at different heights to one another. In some embodiments, the plurality of stacked ILD layers 330a-330b may comprise one or more of silicon dioxide, silicon nitride, carbon doped silicon dioxide, silicon oxynitride, borosilicate glass (BSG), phosphorus silicate glass (PSG), borophosphosilicate glass (BPSG), fluorosilicate glass (FSG), undoped silicate glass (USG), a porous dielectric material, or the like. In various embodiments, the one or more etch stop layers 332a-332b may comprise a carbide (e.g., silicon carbide, silicon oxycarbide, or the like), a nitride (e.g., silicon nitride, silicon oxynitride, or the like), or the like. The metal layers and vias typically comprise a metal, and may comprise copper, aluminum, tantalum, and/or titanium, among others.

In the example of FIG. 3, the ferroelectric field-effect transistor (FeFET) device 100 is arranged between the first metal layer 322 and the second metal layer 324. However, in other embodiments, the FeFET device 100 could be between other (e.g., higher) metal layers. The FeFET device 100 comprises ferroelectric structure 104, which is arranged between oxide semiconductor 106 and the gate structure 102. The source region 108 and a drain region 109 are also arranged over the oxide semiconductor 106 and are separated from the ferroelectric structure 104 by the oxide semiconductor 106. Capping structure 116 can be disposed over the oxide semiconductor 105, and the ILD layers 316 can surround the capping structure 116 and oxide semiconductor 106. In some embodiments, due to the thickness of the FeFET device 100, other areas of the circuit that do not include FeFET devices, may have a via (e.g., 329) with an elongated height, relative to vias (e.g., 328) between other metal layers. Again, due to the presence of the ferroelectric structure 104, which can include ferroelectric layer 110, anti-ferroelectric layer 112, and interlayer 114, the FeFET device 100 may provide denser memory storage than other approaches. Further, in some cases, the orientation of the FeFET device 100 can be “flipped” vertically, such that the gate structure 102 is closer to the second metal layer 324 and the capping structure 116 is closer to the first metal layer 322. The ferroelectric layer 110 and anti-ferroelectric layer 112 can also be “flipped” in various configurations so the ferroelectric layer 110 is closer to the gate structure 102 and the anti-ferroelectric layer 112 is closer to the oxide semiconductor 106 (or vice versa).

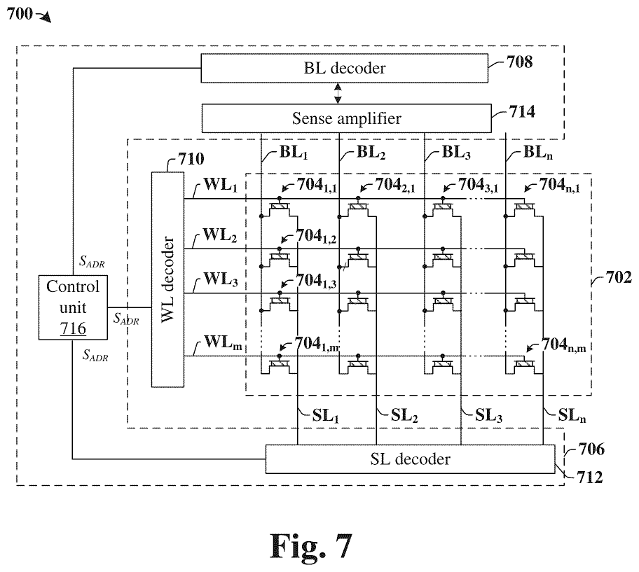

FIG. 4 shows some embodiments of another integrated circuit 400 that includes a semiconductor substrate 302 with an interconnect structure 304 over the semiconductor substrate 302, and wherein the FeFET device 100 has a gate structure 102 whose height corresponds to a height of a gate electrode 312 of a metal oxide semiconductor field effect transistor (MOSFET) 305 on the integrated circuit.

In FIG. 4, the illustrated semiconductor device is again illustrated as a MOSFET 305 as an example; and the features of the MOSFET 305 are labeled to be consistent with FIG. 3 for convenience. The interconnect structure includes again a first metal layer 322, second metal layer 324, and third metal layer 326, as well as higher metal layers (not shown). Each of these metal layers can include metal lines that extend into the plane of the page and/or across the page to connect semiconductor device to one another, thereby achieving a desired circuit configuration. Vias 328, 329 extend vertically through one or more of a plurality of ILD layers 330a-330b and extend between adjacent metal layers to couple metal layers at different heights to one another.

In the example of FIG. 4, the ferroelectric field-effect transistor (FeFET) device 100 is arranged between the first metal layer 322 and the semiconductor substrate 302. Gate electrode 312 of MOSFET 305 and gate structure 102 of FeFET device 100 can have equal thicknesses, and an uppermost surface of gate structure 102 of the FeFET device 100 can be co-planar with an uppermost surface of the gate electrode 312 of the MOSFET 305. The FeFET device 100 comprises ferroelectric structure 104, which is arranged between oxide semiconductor 106 and the gate structure 102. The source region 108 and a drain region 109 are also arranged over the oxide semiconductor 106 and are separated from the ferroelectric structure 104 by the oxide semiconductor 106. Capping structure 116 can be disposed over the oxide semiconductor 105, and the dielectric layer 316 can surround the capping structure 116 and oxide semiconductor 106. Gate dielectric 314 may separate the gate structure 102 of the FeFET from the semiconductor substrate 302. Again, due to the presence of the ferroelectric structure 104, which can include ferroelectric layer 110, anti-ferroelectric layer 112, and interlayer 114, the FeFET device may provide denser memory storage than other approaches.

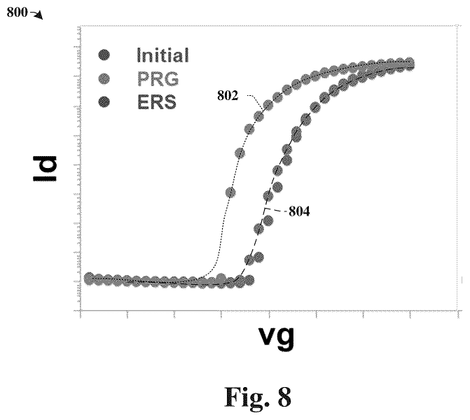

FIG. 5 shows some embodiments of an integrated circuit 500 that includes a semiconductor substrate 302 with an interconnect structure 304 over the semiconductor substrate, and wherein the FeFET device 100 has a gate structure 102 that corresponds to a doped region in the semiconductor substrate 302.

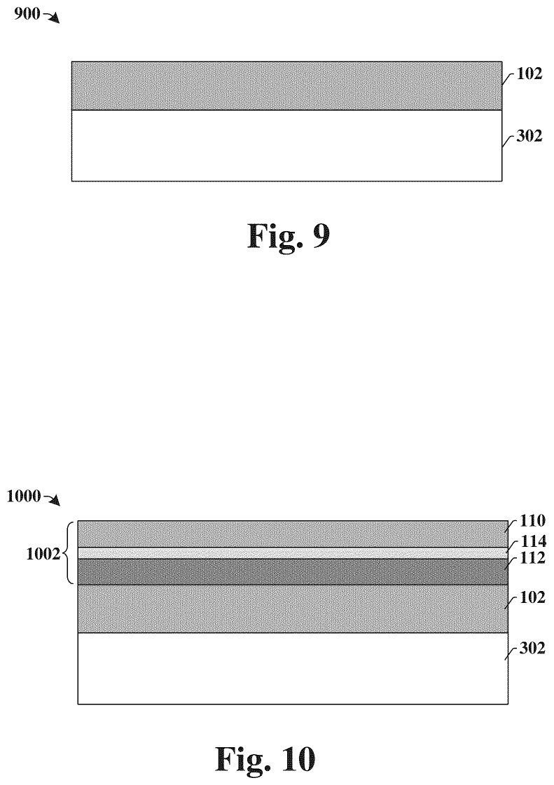

FIG. 6 illustrates a three-dimensional view of some alternative embodiments of an integrated chip 620 comprising a FeFET device having a ferroelectric structure 104 including a ferroelectric layer 110 and anti-ferroelectric layer 112 separated from one another by an interlayer 114. The integrated chip 620 includes a lower dielectric layer 602 disposed over a semiconductor substrate 302. A gate structure 102 is disposed on the lower dielectric layer 602 and a dielectric layer 604 is arranged over the gate structure 102. A ferroelectric structure 104 is arranged on sidewalls of the lower dielectric layer 602, the gate structure 102, and the dielectric layer 604. An oxide semiconductor 106 is arranged along sidewalls of the ferroelectric structure 104 that faces away from the gate structure 102. A source region 108 and a drain region 109 are disposed on a side of the oxide semiconductor 106 and extend perpendicular to an upper surface of the semiconductor substrate 302. The ferroelectric structure 104 include a ferroelectric layer 110 and anti-ferroelectric layer 112, which extend perpendicular to the upper surface of the semiconductor substrate 302 and which are separated from one another by an interlayer 114.

FIG. 7 illustrates an exemplary schematic diagram of FeFET memory circuit 700 having FeFET devices respectively comprising a ferroelectric structure including a ferroelectric layer and anti-ferroelectric layer separated from one another by an interlayer.

The FeFET memory circuit 700 comprises a FeFET memory array 702 including a plurality of FeFET devices 704_{1,1}-704_{n,m}. The plurality of FeFET devices 704_{1,1}-704_{n,m} are arranged within the FeFET memory array 702 in rows and/or columns. The plurality of FeFET devices 704_{1,x}-704_{n,x} within a row are operably coupled to word-lines WLₓ (x=1-m). The plurality of FeFET devices 704_{x,1}-704_{x,m} have respective drains along a column that are operably coupled to bit-lines BLₓ (x=1-n) and have respective sources along a column that are operably coupled to source-lines SLₓ (x=1-n). Each FeFET device 704 can have the structure illustrated in any of FIG. 1-FIG. 6.

The word-lines WL₁-WLₘ, the bit-lines BL₁-BLₙ, and the source-lines SL₁-SLₙ, are coupled to control circuitry 706. In some embodiments, the control circuitry 706 comprises a word-line decoder 710 coupled to the word-lines WL₁-WLₘ, a bit-line decoder 708 coupled to the bit-lines BL₁-BLₙ, and a source-line decoder 712 coupled to the source-lines SL₁-SLₙ. In some embodiments, the control circuitry 706 further comprises a sense amplifier 714 coupled to the bit-lines BL₁-BLₙ or the source-lines SL₁-SLₙ. In some embodiments, the control circuitry 706 further comprises a control unit 716 configured to send address information S_{ADR} to the word-line decoder 710, the bit-line decoder 708, and/or the source-line decoder 412 to enable the control circuitry 706 to selectively access one or more of the plurality of FeFET devices 704_{1,1}-704_{n,m}.

For example, during operation, the control unit 716 is configured to provide address information S_{ADR} to the word-line decoder 710, the bit-line decoder 708, and the source-line decoder 712. Based on the address information S_{ADR}, the word-line decoder 710 is configured to selectively apply a bias voltage to one of the word-lines WL₁-WLₘ. Concurrently, the bit-line decoder 708 is configured to selectively apply a bias voltage to one of the bit-lines BL₁-BLₙ and/or the source-line decoder 712 is configured to selectively apply a bias voltage to one of the source-lines SL₁-SLₙ. By applying bias voltages to selective ones of the word-lines WL₁-WLₘ, the bit-lines BL₁-BLₙ, and/or the source-lines SL₁-SLₙ, the FeFET memory circuit 700 can be operated to write different data states to and/or read data states from the plurality of FeFET devices 704_{1,1}-704_{n,m}.

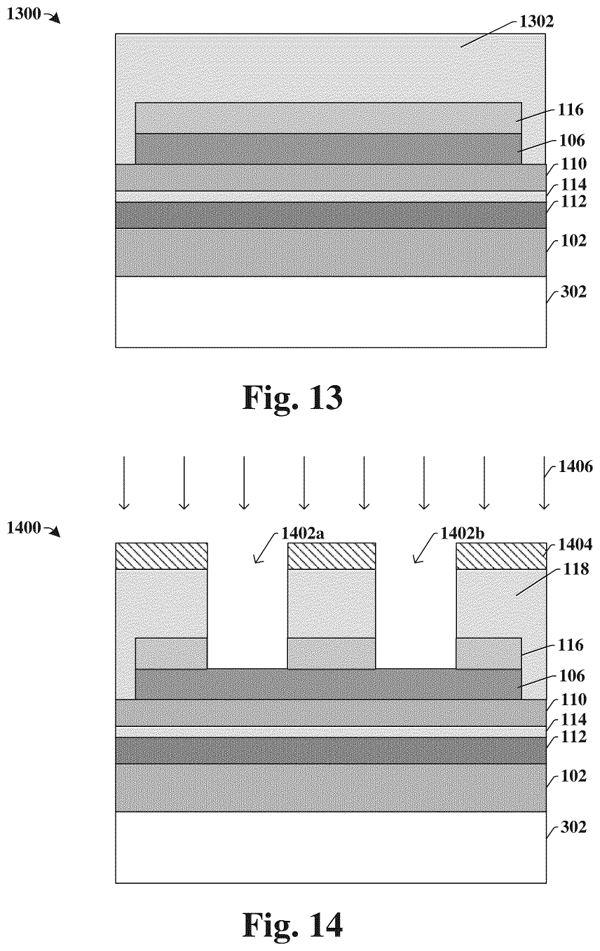

FIG. 8 illustrates a graph 800 showing an exemplary memory window of a FeFET device. As shown in graph 800, when a FeFET device is storing a first data state (e.g., a logical “1”) the FeFET device will have a threshold voltage corresponding to the drain current illustrated by line 802. When the FeFET device is storing a second data state (e.g., a logical “0”) the FeFET device will have a threshold voltage corresponding to the drain current illustrated by line 804.

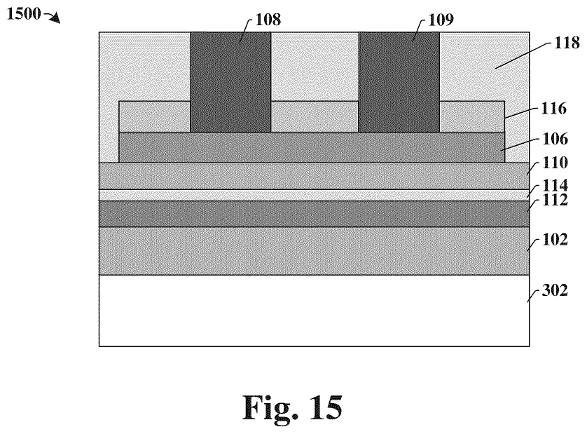

FIGS. 9-15 illustrate cross-sectional views 900-1500 of some embodiments of a method of forming an integrated chip comprising a FeFET device having a polarization enhancement structure. Although FIGS. 9-15 are described in relation to a method, it will be appreciated that the structures disclosed in FIGS. 9-15 are not limited to such a method, but instead may stand alone as structures independent of the method.

As shown in cross-sectional view 900 of FIG. 9, a gate structure 102 is formed. In some embodiments, the gate structure 102 may be formed over a semiconductor substrate 302. In various embodiments, the semiconductor substrate 302 may be any type of semiconductor body (e.g., silicon, SiGe, SOI, etc.), such as a semiconductor wafer and/or one or more die on a wafer, as well as any other type of semiconductor and/or epitaxial layers, associated therewith. The gate structure 102 may comprise one or more conductive materials. In some embodiments, the one or more conductive materials may comprise and/or be a metal such as titanium, titanium nitride, tungsten, tungsten nitride, copper, gold, zinc, aluminum, or the like. In various embodiments, the gate structure 102 may be formed by way of one or more deposition processes (e.g., ALD processes, CVD processes, PE-CVD processes, or the like).

As shown in cross-sectional view 1000 of FIG. 10, a ferroelectric structure 1002 may be formed over the gate structure 102. The ferroelectric structure 1002 may comprise ferroelectric materials. In some embodiments, the one or more ferroelectric materials may comprise hafnium oxide, hafnium zinc oxide, or the like. In various embodiments, the ferroelectric structure 1002 may be formed by way of one or more deposition processes (e.g., ALD processes, CVD processes, PE-CVD processes, or the like). For example, an anti-ferroelectric layer 112 is formed over the gate structure 102, and an interlayer 114 is formed over the anti-ferroelectric layer 112. A ferroelectric layer 110 is then formed over the interlayer 114. In some embodiments, the anti-ferroelectric layer 112 is deposited in-situ with the interlayer 114 in a deposition chamber, and the ferroelectric layer 110 can also be optionally formed in-situ in the deposition chamber. In other cases, the anti-ferroelectric layer 112 is deposited in-situ with the interlayer 114 in the deposition chamber, and the structure is then removed from the deposition chamber before the ferroelectric layer 110 is formed.

As shown in cross-sectional view 1100 of FIG. 11, an oxide semiconductor layer 1102 is formed over the ferroelectric structure 1002. In some embodiments, the one or more oxide semiconductor materials may comprise indium gallium zinc oxide (IGZO), indium gallium zinc tin oxide (IGZTO), indium tungsten oxide (IWO), indium tungsten zinc oxide (IWZO), indium zinc oxide (IZO), zinc oxide (ZnO), or the like. In various embodiments, the oxide semiconductor layer 1102 may be formed by way of one or more deposition processes (e.g., ALD processes, CVD processes, PE-CVD processes, or the like). A capping layer 1104 can be formed over the semiconductor layer. The capping layer 1104 can comprise silicon dioxide and/or a high-k dielectric material (e.g., HfO₂, Al₂O₃, TiO₂). In various embodiments, the capping layer 1104 may be formed by way of one or more deposition processes (e.g., ALD processes, CVD processes, PE-CVD processes, or the like).

As shown in cross-sectional view 1200 of FIG. 12, a first patterning process is performed to pattern the capping layer (e.g., 1104 of FIG. 11) and the oxide semiconductor layer (e.g., 1102 of FIG. 11). The first patterning process removes parts of the oxide semiconductor layer (e.g., 1102 of FIG. 11) to form an oxide semiconductor 106, and parts of the capping layer (e.g., 1104 of FIG. 11) to form a capping structure 116 and to expose an upper surface of the gate structure 102. In some embodiments, the first patterning process may also remove a part of the gate structure 102.

In some embodiments, the first patterning process may selectively expose the oxide semiconductor layer and the ferroelectric layer to a first etchant 1202 according to a first masking structure 1204 formed over capping layers (e.g., 1104 of FIG. 11). In some embodiments, the first masking structure 1204 may comprise a photosensitive material (e.g., a photoresist). In other embodiments, the first masking structure 1204 may comprise a dielectric masking layer (e.g., silicon oxide, silicon dioxide, or the like), a hard mask, and/or the like. In some embodiments, the first etchant 1202 may comprise a dry etchant (e.g., having a fluorine chemistry, a chlorine chemistry, or the like). In other embodiments, the first etchant 1202 may comprise a wet etchant (e.g., comprising hydrofluoric acid, potassium hydroxide, or the like).

As shown in cross-sectional view 1300 of FIG. 13, a dielectric layer 1302 is formed over the capping structure and oxide semiconductor. The dielectric layer 1302 extends along an upper surface and sidewalls of the capping structure and oxide semiconductor. In various embodiments, the dielectric layer 1302 may be formed by way of one or more deposition processes (e.g., ALD processes, CVD processes, PE-CVD processes, or the like).

As shown in cross-sectional view 1400 of FIG. 14, a second patterning process is performed to pattern the dielectric layer 1302 to form a dielectric structure 118, which includes a source contact hole 1402a and a drain contact hole 1402b. In some embodiments, the source contact hole 1402a and the drain contact hole 1402b extend through the dielectric structure 118 and the capping structure 116 to expose upper surfaces of the oxide semiconductor 106. In some embodiments, the second patterning process is performed by selectively exposing the dielectric layer 1302 to a second etchant 1406 according to a second masking structure 1404. In some embodiments, the second etchant 1406 may comprise a dry etchant (e.g., having a fluorine chemistry, a chlorine chemistry, or the like).

As shown in cross-sectional view 1500 of FIG. 15, a conductive material is formed within the source contact hole 1402a, the drain contact hole 1402b. In some embodiments, the conductive material may comprise a metal, such as copper, aluminum, tungsten, cobalt, or the like. In some embodiments the conductive material may be deposited by one or more of a deposition process and a plating process. In some embodiments, a deposition process may be used to form a seed layer of a conductive material followed by a plating process to fill in the source contact hole 1402a and the drain contact hole 1402b. In some embodiments, after formation of the conductive material, a planarization process may be performed to remove excess of the conductive material from over the dielectric layer and to form a source region 108, and a drain region 109.

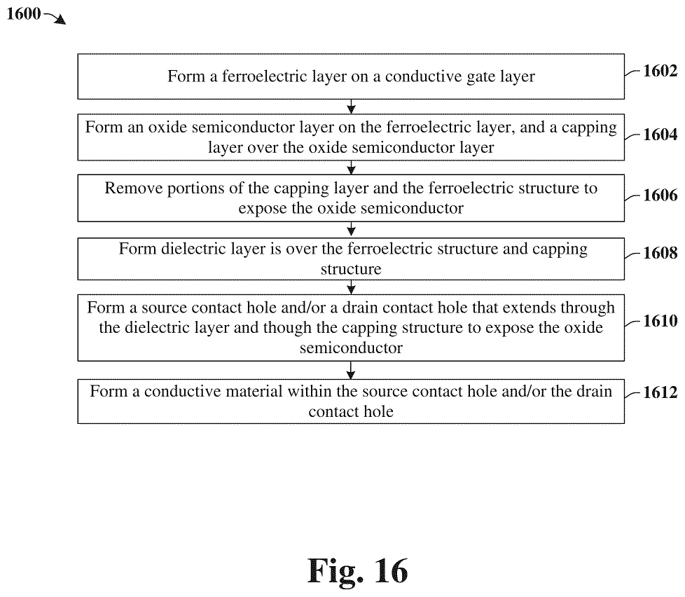

FIG. 16 illustrates a flow diagram of some embodiments of a method 1600 of forming an integrated chip comprising a FeFET device having a polarization enhancement structure.

While the disclosed method 1600 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 1602, a ferroelectric layer is formed on a conductive gate layer. FIG. 10 illustrates a cross-sectional view 1000 of some embodiments corresponding to act 1602.

At act 1604, an oxide semiconductor layer is formed on the ferroelectric layer, and a capping layer is formed over the oxide semiconductor layer. FIG. 11 illustrates a cross-sectional view 1100 of some embodiments corresponding to act 1604.

At act 1606, one or more patterning processes are performed to remove portions of the capping layer and the ferroelectric structure to expose the oxide semiconductor. FIG. 12 illustrates a cross-sectional view 1200 of some embodiments corresponding to act 1606.

At act 1608, a dielectric layer is formed over the ferroelectric structure and capping structure. FIG. 13 illustrates a cross-sectional view 1300 of some embodiments corresponding to act 1608.

At act 1610, one or more additional patterning processes are performed to form a source contact hole and/or a drain contact hole that extend through the dielectric layer and though the capping structure to expose the oxide semiconductor. FIG. 14 illustrates a cross-sectional view 1400 of some embodiments corresponding to act 1610.

At act 1612, a conductive material is formed within the source contact hole and/or the drain contact hole. FIG. 15 illustrates a cross-sectional view 1500 of some embodiments corresponding to act 1612.

Accordingly, in some embodiments, a ferroelectric field-effect transistor (FeFET) device, includes a ferroelectric structure including a ferroelectric layer and an anti-ferroelectric layer; a gate structure disposed along a first face of the anti-ferroelectric layer, such that the anti-ferroelectric layer separates the gate structure from the ferroelectric layer; an oxide semiconductor disposed along a first face of the ferroelectric layer, such that the ferroelectric layer separates the oxide semiconductor from the anti-ferroelectric layer; a source region and a drain region disposed on the oxide semiconductor, wherein the gate structure extends laterally over the anti-ferroelectric layer between the source region and the drain region; and an interlayer separating the ferroelectric layer from the anti-ferroelectric layer.

In some examples, the ferroelectric layer comprises Hf₁₋ₓZrₓO, and the anti-ferroelectric layer comprises Hf_{1-y}Zr_{y}O, where x and y are different.

In some examples, x is between 0 and 0.5, and y is between 0.5 and 1.

In some examples, the interlayer comprises a metal oxide or a metal.

In some examples, the interlayer comprises the metal oxide and the metal oxide comprises titanium oxide, aluminum oxide, magnesium oxide, hafnium oxide, or indium oxide; or wherein the interlayer comprises the metal and the metal comprises titanium, platinum, gold, or nickel.

In some examples, the ferroelectric layer has a first percentage of tetragonal crystalline lattice per unit volume and the anti-ferroelectric layer has a second percentage of tetragonal crystalline lattice per unit volume, the second percentage being greater than the first percentage.

In some examples, a ratio of a first percentage of orthorhombic crystal per unit volume in the ferroelectric layer to a second percentage of tetragonal crystal per unit volume in the anti-ferroelectric layer is in a range of 15:1 to 25:1.

In some examples, at least one of the ferroelectric layer or the anti-ferroelectric layer is a polycrystalline structure where crystalline grains are separated from one another by grain boundaries, and the crystalline grains have an average grain size of more than 20 microns.

In some examples, the interlayer has a coefficient of thermal expansion of 1×10-4 m/Kelvin (K) to 1×10-6 m/K.

In some examples, the interlayer has a thickness of less than 1 nanometer.

In some examples, the oxide semiconductor comprises one or more of indium gallium zinc oxide, indium gallium zinc tin oxide, indium tungsten oxide, indium tungsten zinc oxide, indium zinc oxide, or zinc oxide.

In some examples, the source region is coupled to a source-line, the drain region is coupled to a bit-line, and the gate structure is coupled to a word-line.

In some examples, FeFET device further includes a substrate; wherein the gate structure is disposed along a first side of the substrate; and wherein the gate structure is vertically disposed between the first side of the substrate and the ferroelectric structure.

In some examples, an integrated chip includes a semiconductor substrate; a conductive gate structure arranged over the semiconductor substrate; an anti-ferroelectric layer arranged over the conductive gate structure; an interlayer comprising a metal or metal oxide having a lower surface in direct contact with an upper surface of the anti-ferroelectric layer; a ferroelectric layer having a lower surface in direct contact with an upper surface of the interlayer; an oxide semiconductor arranged over the ferroelectric layer, the oxide semiconductor including a channel region directly over the conductive gate structure; and a source region and a drain region disposed on the oxide semiconductor and laterally spaced apart from one another by a length corresponding to the channel region.

In some examples, the ferroelectric layer has a first percentage of tetragonal crystalline lattice per unit volume and the anti-ferroelectric layer has a second percentage of tetragonal crystalline lattice per unit volume, the second percentage being greater than the first percentage.

In some examples, in the ferroelectric layer includes Hf₁₋ₓZrₓO, and the anti-ferroelectric layer includes Hf_{1-y}Zr_{y}O, where x is less than 0.5 and greater than 0, and y is greater than 0.5 and less than 1.

In some examples, a method of forming a FeFET device includes receiving a substrate; forming a gate structure over the gate structure; forming an anti-ferroelectric layer over the gate structure; forming a interlayer comprising a metal or metal oxide having a lower surface in direct contact with an upper surface of the anti-ferroelectric layer; forming a ferroelectric layer having a lower surface in direct contact with an upper surface of the interlayer; forming an oxide semiconductor layer over the ferroelectric layer; forming a dielectric layer over the oxide semiconductor layer; performing a first patterning process to form a source opening and a drain opening through the dielectric layer to expose the oxide semiconductor layer; and forming a conductive material within the source opening and the drain opening.

In some examples, the anti-ferroelectric layer and the interlayer are formed in-situ within a deposition chamber.

In some examples, the anti-ferroelectric layer, the interlayer, and the ferroelectric layer are formed in-situ within a deposition chamber.

In some examples, the oxide semiconductor layer comprises indium gallium zinc oxide, indium gallium zinc tin oxide, indium tungsten oxide, indium tungsten zinc oxide, indium zinc oxide, or zinc oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A ferroelectric field-effect transistor (FeFET) device, comprising:
a ferroelectric structure including a ferroelectric layer and an anti-ferroelectric layer;
a gate structure disposed along a first face of the anti-ferroelectric layer, such that the anti-ferroelectric layer separates the gate structure from the ferroelectric layer;
an oxide semiconductor disposed along a first face of the ferroelectric layer, such that the ferroelectric layer separates the oxide semiconductor from the anti-ferroelectric layer;
a source region and a drain region disposed on the oxide semiconductor, wherein the gate structure extends laterally over the anti-ferroelectric layer between the source region and the drain region; and
an interlayer separating the ferroelectric layer from the anti-ferroelectric layer.

2. The FeFET device of claim 1, wherein the ferroelectric layer comprises Hf₁₋ₓZrₓO, and the anti-ferroelectric layer comprises Hf_{1-y}Zr_{y}O, where x and y are different.

3. The FeFET device of claim 2, wherein x is between 0 and 0.5, and y is between 0.5 and 1.

4. The FeFET device of claim 1, wherein the interlayer comprises a metal oxide or a metal.

5. The FeFET device of claim 4, wherein the interlayer comprises the metal oxide and the metal oxide comprises titanium oxide, aluminum oxide, magnesium oxide, hafnium oxide, or indium oxide; or wherein the interlayer comprises the metal and the metal comprises titanium, platinum, gold, or nickel.

6. The FeFET device of claim 1, wherein the ferroelectric layer has a first percentage of tetragonal crystalline lattice per unit volume and the anti-ferroelectric layer has a second percentage of tetragonal crystalline lattice per unit volume, the second percentage being greater than the first percentage.

7. The FeFET device of claim 1, wherein a ratio of a first percentage of orthorhombic crystal per unit volume in the ferroelectric layer to a second percentage of tetragonal crystal per unit volume in the anti-ferroelectric layer is in a range of 15:1 to 25:1.

8. The FeFET device of claim 7, wherein at least one of the ferroelectric layer or the anti-ferroelectric layer is a polycrystalline structure where crystalline grains are separated from one another by grain boundaries, and the crystalline grains have an average grain size of more than 20 microns.

9. The FeFET device of claim 1, wherein the interlayer has a coefficient of thermal expansion of 1×10-4 m/Kelvin (K) to 1×10-6 m/K.

10. The FeFET device of claim 1, wherein the interlayer has a thickness of less than 1 nanometer.

11. The FeFET device of claim 1, wherein the oxide semiconductor comprises one or more of indium gallium zinc oxide, indium gallium zinc tin oxide, indium tungsten oxide, indium tungsten zinc oxide, indium zinc oxide, or zinc oxide.

12. The FeFET device of claim 1, wherein the source region is coupled to a source-line, the drain region is coupled to a bit-line, and the gate structure is coupled to a word-line.

13. The FeFET device of claim 1, further comprising:
a substrate;
wherein the gate structure is disposed along a first side of the substrate; and
wherein the gate structure is vertically disposed between the first side of the substrate and the ferroelectric structure.

14. An integrated chip, comprising:
a semiconductor substrate;
a conductive gate structure arranged over the semiconductor substrate;
an anti-ferroelectric layer arranged over the conductive gate structure;
an interlayer comprising a metal or metal oxide having a lower surface in direct contact with an upper surface of the anti-ferroelectric layer;
a ferroelectric layer having a lower surface in direct contact with an upper surface of the interlayer;
an oxide semiconductor arranged over the ferroelectric layer, the oxide semiconductor including a channel region directly over the conductive gate structure; and
a source region and a drain region disposed on the oxide semiconductor and laterally spaced apart from one another by a length corresponding to the channel region.

15. The integrated chip of claim 14, wherein the ferroelectric layer has a first percentage of tetragonal crystalline lattice per unit volume and the anti-ferroelectric layer has a second percentage of tetragonal crystalline lattice per unit volume, the second percentage being greater than the first percentage.

16. The integrated chip of claim 14, wherein the ferroelectric layer comprises Hf₁₋ₓZrₓO, and the anti-ferroelectric layer comprises Hf_{1-y}Zr_{y}O, where x is less than 0.5 and greater than 0, and y is greater than 0.5 and less than 1.

17. A method of forming a FeFET device, comprising:
receiving a substrate;
forming a gate structure over the gate structure;
forming an anti-ferroelectric layer over the gate structure;
forming a interlayer comprising a metal or metal oxide having a lower surface in direct contact with an upper surface of the anti-ferroelectric layer;
forming a ferroelectric layer having a lower surface in direct contact with an upper surface of the interlayer;
forming an oxide semiconductor layer over the ferroelectric layer;
forming a dielectric layer over the oxide semiconductor layer;
performing a first patterning process to form a source opening and a drain opening through the dielectric layer to expose the oxide semiconductor layer; and
forming a conductive material within the source opening and the drain opening.

18. The method of claim 17, wherein the anti-ferroelectric layer and the interlayer are formed in-situ within a deposition chamber.

19. The method of claim 17, wherein the anti-ferroelectric layer, the interlayer, and the ferroelectric layer are formed in-situ within a deposition chamber.

20. The method of claim 17, wherein the oxide semiconductor layer comprises indium gallium zinc oxide, indium gallium zinc tin oxide, indium tungsten oxide, indium tungsten zinc oxide, indium zinc oxide, or zinc oxide.
